(19) United States
(12) Patent Application Publication
(10) Pub. No.: US 2010/0025682 A1
(43) Pub. Date: Feb. 4, 2010

(54) Interface device for wireless testing, semiconductor device and semiconductor package including the same, and method for wirelessly testing using the same

(75) Inventors: Sang-Hoon Lee, Hwaseong-si (KR); Eun-Jo Byun, Yongin-si (KR); Se-Jang Oh, Seongnam-si (KR); Young-Soo An, Yongin-si (KR); Chang-Hyun Cho, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/462,373

(22) Filed: Aug. 3, 2009

(30) Foreign Application Priority Data
Aug. 4, 2008 (KR) 10-2008-0076148

(51) Int. Cl. H01L 21/66; H01L 23/00

(52) U.S. Cl. 257/48; 257/E23.002; 257/E21.521

(57) ABSTRACT

In an interface device for wireless testing capable of testing a semiconductor chip in a non-contact manner, a semiconductor device and a semiconductor package including the same, and a method for wirelessly testing a semiconductor device using the same are provided, the interface device for wireless testing includes an interface substrate, interface antennas on the interface substrate, and interface transmitting and receiving circuits on the interface substrate, wherein the interface transmitting and receiving circuits are electrically connected to input/output pads of a semiconductor chip via interface vias passing through the interface substrate.

### PRIORITY STATEMENT

This application claims the benefit of priority under 35 U.S.C. §119 from Korean Patent Application No. 10-2008-0076148, filed on Aug. 4, 2008, the contents of which are hereby incorporated herein by reference in their entirety.

### BACKGROUND

1. Field

Exemplary embodiments relate to an interface device for wirelessly testing a semiconductor chip, a semiconductor device and a semiconductor package including the same, and a method for wirelessly testing a semiconductor chip using the same.

2. Description of Related Art

The steady pace of the development of semiconductor manufacturing technology continues to lead to ever-smaller semiconductor devices. This, is turn, continues to lead to a reduction in the size of semiconductor packages. Accordingly, input/output (I/O) pads of semiconductor chips and the spacing, or interval, therebetween continues to become smaller. Since smaller input/output pads are more physically weak, they are more likely to become damaged when a needle of a test apparatus applies force to the input/output pads when the needle is brought into physical contact with the input/output pads during testing of the semiconductor device.

### SUMMARY

Exemplary embodiments provide various interface devices for wireless testing for testing of a semiconductor device in a non-contact manner.

Exemplary embodiments also provide a semiconductor device including various interface devices for wireless testing.

Exemplary embodiments also provide a semiconductor package including various interface devices for wireless testing.

Exemplary embodiments also provide a method for testing a semiconductor device in a non-contact manner using various interface devices for wireless testing.

Exemplary embodiments are directed to an interface device for wireless testing including: an interface substrate; interface antennas on the interface substrate; and interface transmitting and receiving circuits on the interface substrate electrically connected to the interface antennas via interface interconnections on the interface substrate. The interface transmitting and receiving circuits are electrically connected to input/output pads of a semiconductor chip via interface vias passing through the interface substrate.

Other exemplary embodiments are directed to a semiconductor device including: a semiconductor chip at a wafer level; input/output pads on the semiconductor chip; and an interface device for wireless testing on the semiconductor chip. The interface device includes: an interface substrate; interface antennas on the interface substrate; and interface transmitting and receiving circuits on the interface substrate electrically connected to the interface antennas via interface interconnections on the interface substrate, and the interface transmitting and receiving circuits are electrically connected to the input/output pads of the semiconductor chip via interface vias, and the interface vias pass through the interface substrates.

In one embodiment, the interface substrate comprises an insulating hard substrate, the insulating hard substrate being one of a printed circuit board (PCB) substrate, a plastic substrate, a glass substrate, and a ceramic substrate.

In another embodiment, each interface antenna comprises a polygonal or circular coil.

In another embodiment, each interface transmitting and receiving circuit comprises a transmitting circuit and a receiving circuit that in turn comprises resistors, capacitors and transistors.

In another embodiment, the interface substrate comprises at least two layers comprising an upper interface substrate and a lower interface substrate.

In another embodiment, the interface vias comprise upper interface vias passing through the upper interface substrate, and lower interface vias passing through the lower interface substrate.

In another embodiment, the interface antennas are disposed on the upper interface substrate and the interface transmitting and receiving circuits are disposed on the lower interface substrate.

In another embodiment, the upper interface vias electrically connect the interface antennas to the interface transmitting and receiving circuits, and the lower interface vias electrically connect the interface transmitting and receiving circuits to the input/output pads of the semiconductor chip.

In another embodiment, the interface device further comprises interface pads disposed between the interface transmitting and receiving circuits and the input/output pads of the semiconductor chip, for electrically connecting the interface transmitting and receiving circuits to the input/output pads of the semiconductor chip.

In another embodiment, the input/output pads of the semiconductor chip are disposed in a central region on an upper surface of the semiconductor chip, and the interface antennas are disposed in a region corresponding to outer edges of the interface substrate.

Still other exemplary embodiments are directed to a semiconductor package including: a semiconductor chip; input/output pads formed on the semiconductor chip; and an interface device for wireless testing formed on the semiconductor chip. The interface device includes: an interface substrate; interface antennas formed on the interface substrate; and interface transmitting and receiving circuits formed on the interface substrate electrically connected to the interface antennas via interface interconnections on the interface substrate, and the interface antennas are electrically connected to input/output pins via bonding wires.

Yet other exemplary embodiments are directed to a semiconductor package including: a semiconductor chip; input/output pads on the semiconductor chip; and an interface device for wireless testing on the semiconductor chip. The interface device includes: an interface substrate; interface antennas on the interface substrate; and interface transmitting and receiving circuits on the interface substrate electrically connected to the interface antennas via interface interconnections on the interface substrate, and the interface antennas are electrically connected to external solder balls via bumps.

Yet other exemplary embodiments are directed to a method for wirelessly testing a semiconductor chip, the method including: generating, by a controller of a test device, a test signal for testing the semiconductor chip; transmitting the generated test signal to a wireless probe card antenna of a wireless probe card; wirelessly transmitting the test signal from the wireless probe card antenna to an interface antenna of an interface for wireless testing; transmitting the test signal from the interface antenna to the semiconductor chip; and transmitting, by the semiconductor chip, a response signal in response to the test signal, the response signal being transmitted to the controller of the test device in reverse order from that in which the test signal was transmitted.

Yet other exemplary embodiments are included in the detailed description and figures.

### BRIEF DESCRIPTION OF THE DRAWINGS

Exemplary embodiments are described in further detail below with reference to the accompanying drawings. It should be understood that various aspects of the drawings may have been exaggerated for clarity.

FIG. 1 is a conceptual diagram for assisting in understanding exemplary embodiments of the inventive concept, including a plan view of a semiconductor chip with pads arranged in two rows in a central portion and an enlarged plan view of an interface substrate for wireless testing;

FIGS. 2 to 9 are cross-sectional schematic views illustrating wafer-level testing of a semiconductor chip using interface devices for wireless testing according to exemplary embodiments of the inventive concept;

FIG. 10 is a cross-sectional view illustrating a semiconductor chip implemented using a wafer-level redistribution scheme according to the inventive concept; and

FIGS. 11A and 11B are cross-sectional schematic longitudinal views illustrating semiconductor packages having an interface device for wireless testing according to exemplary embodiments of the inventive concept.

### DETAILED DESCRIPTION OF EMBODIMENTS

Various exemplary embodiments will now be described more fully with reference to the accompanying drawings in which some exemplary embodiments are shown. In the drawings, the thicknesses of layers and regions may be exaggerated for clarity.

Detailed illustrative embodiments are disclosed herein. However, specific structural and functional details disclosed herein are merely representative for purposes of describing exemplary embodiments. The invention, however, may be embodied in many alternate forms and should not be construed as limited to only exemplary embodiments set forth herein.

Accordingly, while exemplary embodiments are capable of various modifications and alternative forms, embodiments thereof are shown by way of example in the drawings and will herein be described in detail. It should be understood, however, that there is no intent to limit exemplary embodiments to the particular forms disclosed, but on the contrary, exemplary embodiments are to cover all modifications, equivalents, and alternatives falling within the scope of the invention.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of exemplary embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe exemplary embodiments, various aspects will be described in detail with reference to the attached drawings. However, the inventive concept is not limited to exemplary embodiments described.

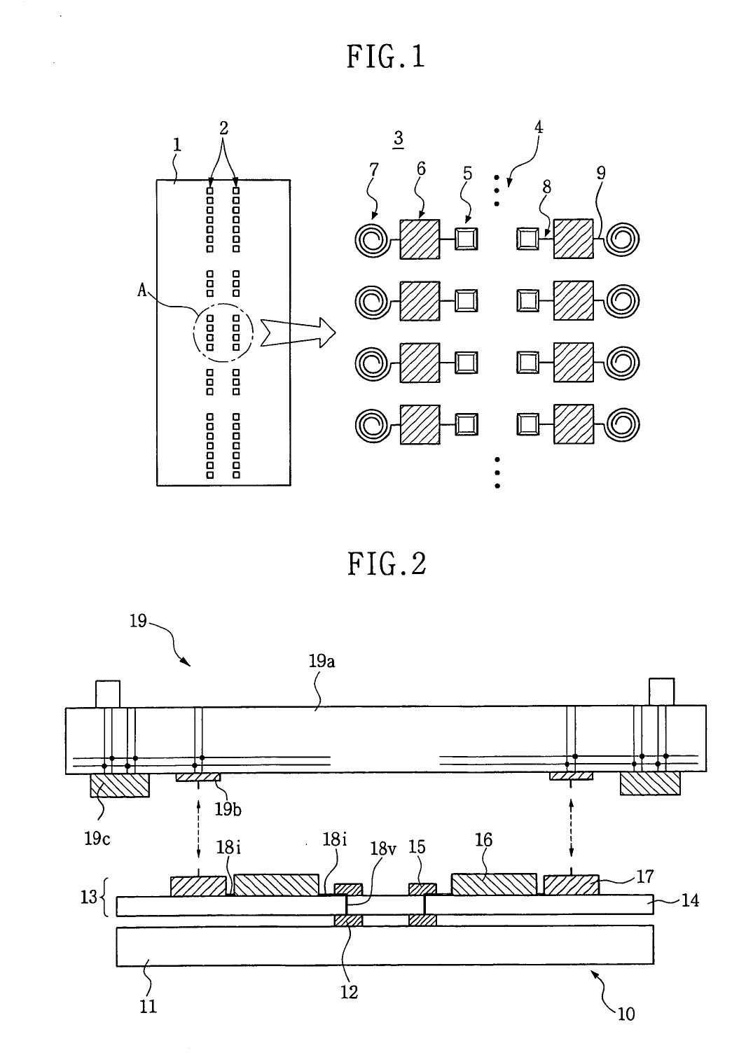

FIG. 1 is a conceptual diagram for assisting in understanding exemplary embodiments of the inventive concept, in which a plan view of a semiconductor chip with pads arranged in two rows in a central portion and an enlarged plan view of an interface substrate for wireless testing, are shown.

A plan view of a semiconductor chip 1 at a wafer level is shown on the left in FIG. 1, in which a plurality of input/output pads 2 are arranged in two rows in a central portion of the semiconductor chip 1 on an upper surface thereof. In FIG. 1, the semiconductor chip 1 may for example, be at a wafer level. In other cases, the input/output pads 2 of a number and of an arrangement shape according to semiconductor standards may be arranged on the semiconductor chip 1. For example, for semiconductor chips at wafer levels or for semiconductor chips directly mounted on a circuit substrate, input/output pads may be arranged in an array of ball grids to correspond with ball contacts. Accordingly, it should be understood that FIG. 1 only illustrates any one of various semiconductor chips on the left, and the shape of the shown semiconductor chip, and the sizes, shape of arrangement, and order of the input/output pads may be changed according to various standards.

A partially enlarged conceptual view of an interface device for wireless testing according to exemplary embodiments of the inventive concept, corresponding to a portion indicated by circle A on the left side of FIG. 1, is shown on the right side of FIG. 1. The interface device 3 for wireless testing according to exemplary embodiments of the inventive concept includes interface pads 5, interface transmitting and receiving circuits 6, and interface antennas 7 that are disposed on an interface substrate 4 and electrically connected to each other. The interface pads 5 correspond to the input/output pads 2 of the semiconductor chip 1, respectively. The interface pads 5 also correspond to the interface transmitting and receiving circuits 6 and the interface antennas 7, respectively, and may be electrically connected to them via interface interconnections 8 and 9. In exemplary embodiments of the inventive concept, the interface device shown on the right side FIG. 1 is not applied to all semiconductor chips, but may be variably changed in shape.

The interface substrate 4 may be any of a printed circuit board (PCB) substrate, a plastic substrate, a glass substrate, ceramic substrate, and other insulating hard substrates.

The interface antennas 7 may be formed as polygonal or circular coils. In the present exemplary embodiment, the interface antennas 7 are shown as the circular coils for the purpose of example. Details of the interface antennas 7 will be described below.

The interface transmitting and receiving circuits 6 may each include a transmitting circuit and a receiving circuit that include, on the interface substrate 4, passive devices such as resistors, capacitors, and interconnections for electrically connecting the passive devices. The interface transmitting and receiving circuits 6 may further each include active devices, such as transistors.

FIG. 2 is a schematic view illustrating testing of a semiconductor chip at a wafer level using an interface device for wireless testing according to a first exemplary embodiment of the inventive concept. Referring to FIG. 2, a semiconductor device 10 includes a semiconductor chip 11 at a wafer level, and an interface device 13 for wireless testing according to the first exemplary embodiment of the inventive concept disposed on the semiconductor chip 11, which wirelessly communicates signals using a wireless probe card 19 during a testing process.

The wireless probe card 19 includes a wireless probe card plate 19a, wireless probe card antennas 19b, and wireless probe card transmitting and receiving circuits 19c, all being electrically connected to a controller (not shown). The wireless probe card 19 may be formed, for example, as a wafer or semiconductor chip. In exemplary embodiments of the inventive concept, the wireless probe card 19 comprises a wafer, configured to allow a plurality of semiconductor chips disposed on a same, common, wafer to be simultaneously tested. For purposes of the present disclosure, to provide understanding of the inventive concept, it is assumed in the present embodiment that one wireless probe card 19 is used to test one semiconductor chip 11.

The interface device for wireless testing 13 according to the first exemplary embodiment of the inventive concept includes interface transmitting and receiving circuits 16 and interface antennas 17 that are disposed on the interface substrate 14. The interface device for wireless testing 13 may further include interface pads 15. The interface device for wireless testing according to exemplary embodiments of the inventive concept may be mounted on a hard panel or may be formed on a wafer using redistribution structure. Details of such exemplary embodiments will be described below.

The interface antennas 17 can be electrically connected to the input/output pads 12 of the semiconductor chip 11 via interface interconnections 18i and interface vias 18v. The interface antennas 17 can be electrically connected to the interface transmitting and receiving circuits 16 via the interface interconnections 18i, the interface transmitting and receiving circuits 16 can be electrically connected to the interface pads 15 via the interface interconnections 18i, and the interface pads 15 can be electrically connected to the input/output pads 12 of the semiconductor chip via the interface vias 18v. In other embodiments, the interface pads 15 need not be provided. In this case, the interface transmitting and receiving circuits 16 can be directly connected to the input/output pads 12 of the semiconductor chip via the interface interconnections 18i and the interface vias 18v. In exemplary embodiments of the inventive concept, the interface antennas 17 can serve as the input/output pads of the semiconductor chip in a packaging process. That is, the interface antennas 17 are connected by bonding wires, bumps, or solder balls into the semiconductor package. A further description of the semiconductor package will be described below.

The interface antennas 17 may be electrically connected to the interface transmitting and receiving circuits 16 via the interface interconnections 18i formed on the interface substrate 14.

The interface vias 18v pass through the interface substrate 14 and can be formed, for example, by filling formed via holes with a conductive material such as metal. The via holes can be formed using any suitable one of physical drilling, laser drilling using light, and chemical etching selected according to a property of each interface substrate. The via plugs can be formed using any of various known schemes, such as deposition, flow-based filling, or via-stud insertion.

The interface pads 15 can be formed as bumps or solder balls. Alternatively, the interface pads 15 can be formed as hexahedral mesas. Alternatively, the interface pads 15 may be formed in a circular or polygonal shape with inclined sidewalls.

In the present exemplary embodiment and other exemplary embodiments of the inventive concept, a space between the interface substrate 14 and the upper surface of the semiconductor chip 11 can be filled with an insulating material such as epoxy resin.

The interface device for wireless testing 13 according to the present exemplary embodiment and other exemplary embodiments of the inventive concept can be separately fabricated according to standards of the semiconductor chip 11 and then mounted on the semiconductor chip 11. In this case, the semiconductor chip 11 at a wafer level that is to be subject to wireless testing can be completed in a convenient and simple manner using a simple adhering process at a location other than a clean room.

Test signals for the semiconductor chip 11 at a wafer level may be generated by a controller (not shown) of the test device, transmitted to the wireless probe card antennas 19b of the wireless probe card 19 via the wireless probe card transmitting and receiving circuits 19c, and wirelessly transmitted to the interface antennas 17. The test signals received at the interface antennas 17 may be transmitted to the semiconductor chip 11 via the interface transmitting and receiving circuits 16 and the interface pads 15. In response to the test signals, the semiconductor chip 11 will generate response signals, which may be transmitted to the controller of the test device via the interface device for wireless testing 13 and the wireless probe card 19 in reverse order from that in which the testing signals were transmitted.

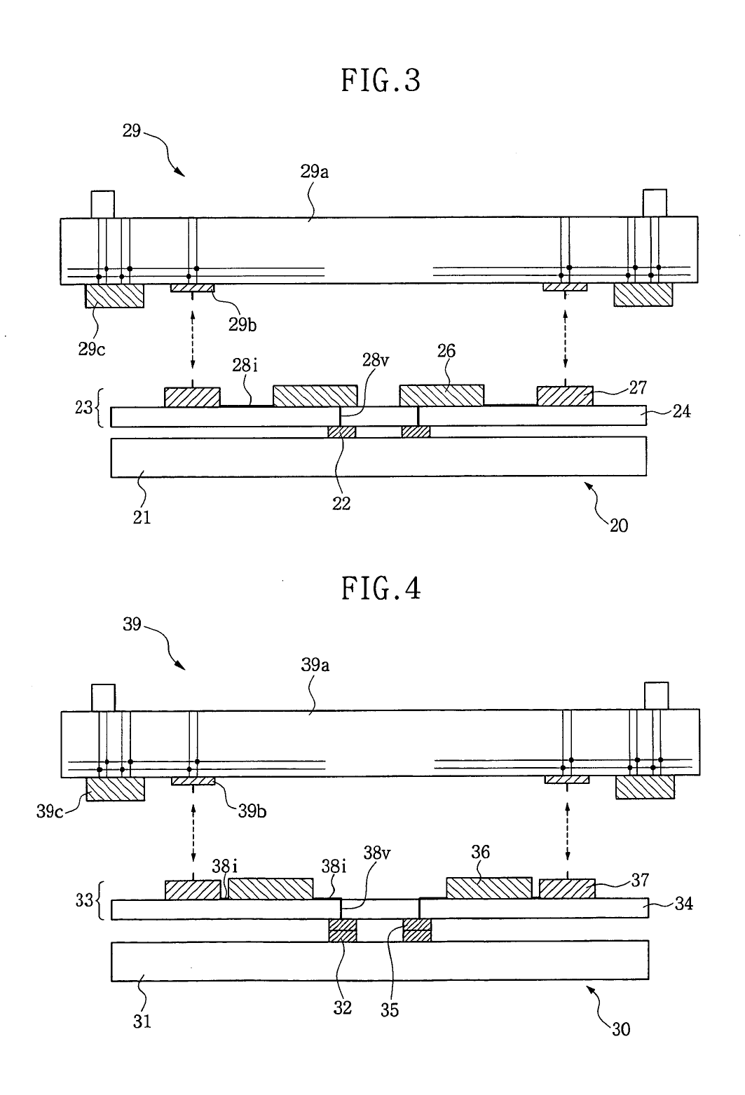

FIG. 3 is a schematic view illustrating a test of a semiconductor chip at a wafer level using an interface device for wireless testing according to a second exemplary embodiment of the inventive concept. Referring to FIG. 3, the semiconductor device 20 includes a semiconductor chip 21 at a wafer level, and an interface device for wireless testing 23 according to the second exemplary embodiment of the inventive concept disposed on the semiconductor chip 21, which communicates signals with the wireless probe card 29 in a test process.

The wireless interface device 23 according to the second exemplary embodiment includes interface transmitting and receiving circuits 26 and interface antennas 27, which are disposed on an interface substrate 24, in which the interface transmitting and receiving circuits 26 may be aligned with input/output pads 22 of the semiconductor chip to be positioned above the pads. Specifically, the interface transmitting and receiving circuits 26 may be directly connected to the input/output pads 22 of the semiconductor chip via interface vias 28v passing through the interface substrate 24, without the interface pads 15 shown in FIG. 2. In this case, an area occupied by the interface pads 15 in the embodiment described above in connection with FIG. 2 may instead be utilized to dispose the interface transmitting and receiving circuits 26 or the interface antennas 27.

FIG. 4 is a schematic view illustrating testing of a semiconductor chip at a wafer level using an interface device for wireless testing according to a third exemplary embodiment of the inventive concept. Referring to FIG. 4, a semiconductor device 30 includes a semiconductor chip 31 at a wafer level, and an interface device for wireless testing 33 according to the third exemplary embodiment of the inventive concept disposed on the semiconductor chip 31, which communicates signals with a wireless probe card 39 in a test process.

The interface device for wireless testing 33 according to the third exemplary embodiment of the inventive concept includes interface transmitting and receiving circuits 36 and interface antennas 37 disposed on an upper surface of an interface substrate 34, and interface pads 35 disposed on a lower surface of the interface substrate 34.

The interface pads 35 may be configured to be physically and electrically connected to input/output pads 32 of the semiconductor chip. The interface pads 35 may have a configuration as described above. In the present exemplary embodiment, particularly, the interface pads 35 are electrically connected to the input/output pads 32 of the semiconductor chip using conductive adhesive or using any of other suitable connecting configurations, including soldering. Examples of conductive adhesives include anisotropic conductive film (ACF) and anisotropic conductive paste (ACP). The conductive adhesive can, for example, be formed of an adhesive polymer resin composition containing conductive particles such as metallic balls. When the interface pads 35 are adhered to the input/output pads 32 of the semiconductor chip using the conductive adhesive, a space between the interface substrate 34 and an upper surface of the semiconductor chip 31 does not have to be filled with separate filler, or, alternatively, can be filled. The configuration of the present exemplary embodiment can be applied to other exemplary embodiments.

In the present exemplary embodiment, the interface pads 35 may be electrically connected to the interface transmitting and receiving circuits 36 via interface vias 38v passing through the interface substrates 34 and interface interconnections 38i. Further, the interface transmitting and receiving circuits 36 and the interface pads 35 may be aligned with each other, as in the above-described exemplary embodiments. Since details of the present exemplary embodiment can be readily inferred from FIG. 3 and the corresponding description, they will not be described in detail in connection with the present embodiment

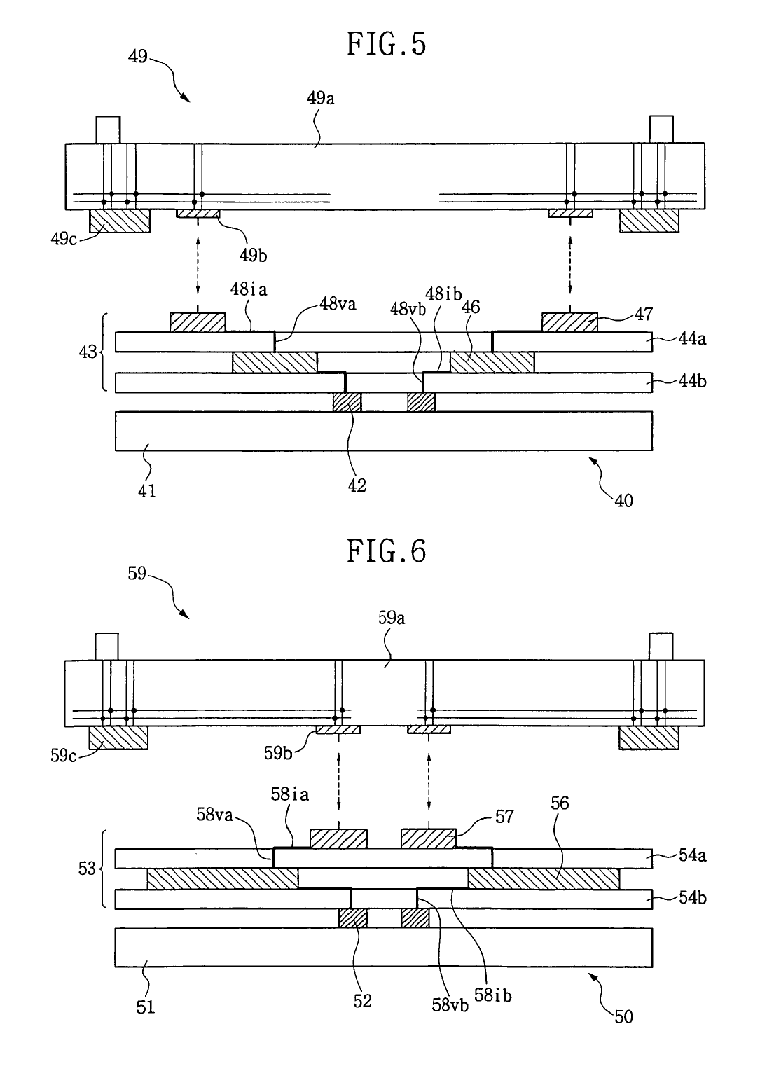

FIG. 5 is a schematic view illustrating testing of a semiconductor chip at a wafer level using an interface device for wireless testing according to a fourth exemplary embodiment of the inventive concept. Referring to FIG. 5, a semiconductor device 40 includes a semiconductor chip 41 at a wafer level, and an interface device for wireless testing 43 according to the fourth exemplary embodiment of the inventive concept disposed on the semiconductor chip 41, which communicates signals with a wireless probe card 49 in a test process.

The interface device for wireless testing 43 according to the fourth exemplary embodiment includes at least two interface substrates 44a and 44b, in which interface antennas 47 are disposed on the upper interface substrate 44a, and interface transmitting and receiving circuits 46 are disposed on the lower interface substrate 44b. Interface pads (not shown) may be further disposed on a lower surface of the lower interface substrate 44b.

In the fourth exemplary embodiment, the interface antennas 47 are shown as being electrically connected to the interface transmitting and receiving circuits 46 via upper interface interconnections 48ia disposed on the upper interface substrate 44a and upper interface vias 48va passing through the upper interface substrate 44a, and the interface transmitting and receiving circuits 46 may be electrically connected to the input/output pads 42 of the semiconductor chip via lower interface interconnections 48ib disposed on the lower interface substrate 44b and lower interface vias 48vb passing through the lower interface substrate 44b. Interface pads (not shown) are optionally further disposed on an upper or lower surface of the lower interface substrate 44b. In this case, the interface transmitting and receiving circuits 46 are electrically connected to the interface pads, which may be electrically connected to the input/output pads 42 of the semiconductor chip. Since details of the present exemplary embodiment can be sufficiently inferred from the above figures and the corresponding descriptions, they will not be described.

Although in the fourth exemplary embodiment, the interface antennas 47, the interface transmitting and receiving circuits 46, and the input/output pads 42 of the semiconductor chip are shown not to overlap with each other, they may optionally be disposed to be aligned and overlap with each other. That is, the interface antennas 47, the interface transmitting and receiving circuits 46, and the input/output pads 42 of the semiconductor chip may be directly connected via the upper and lower interface vias 46va and 48vb. Alternatively, only the interface antennas 47 and the interface transmitting and receiving circuits 46 are disposed to be aligned or overlap with each other via the upper interface vias 48va, and only the interface transmitting and receiving circuits 46 and the input/output pads 42 of the semiconductor chip are disposed to be aligned or overlap with each other via the lower interface vias 48vb. Since details of the exemplary embodiments in which the interface pads are formed are sufficiently inferred from the above description, they will not be described in connection with the present embodiment.

In the fourth exemplary embodiment, the input/output pads 42 of the semiconductor chip are shown as being disposed in a central portion thereof, and the interface antennas 47 are disposed on edges of the upper interface substrate 44a. The interface transmitting and receiving circuits 46 are disposed on the lower interface substrate 44b between the input/output pads 42 of the semiconductor chip and the interface antennas 47.

In the fourth exemplary embodiment, when the semiconductor chip 41 has a size that is smaller than a minimal area required by the interface device 43, the respective interface components may all be integrated into the semiconductor chip 41. One interface transmitting and receiving circuit 46 and one interface antenna 47 are assigned to each of the input/output pads 42 of the semiconductor chip. Accordingly, when a number of the input/output pads 42 of the semiconductor chip increases, numbers of the interface transmitting and receiving circuits 46 and the interface antennas 47 also correspondingly increase. When this makes it difficult for all the interface components to be disposed on the same, common, interface substrate, the interface transmitting and receiving circuits 46 and the interface antennas 47 are disposed on the different interface substrates 44a and 44b as in the present exemplary embodiment, resulting in an interface device 43 for a high-integration semiconductor chip 41 and therefore having more input/output pads 42.

In the fourth exemplary embodiment, a distance between the interface components, i.e., the interface interconnections 48ia and 48ib and the interface vias 48va and 48vb may be used to adjust input/output impedance of the interface device 43. For example, the same effect as the respective interface components, and particularly, resistors or reactors that must be included in the interface transmitting and receiving circuit 46 being separately disposed is obtained. This can further reduce an area occupied by the respective interface components. This is effective even in other exemplary embodiments of the inventive concept.

FIG. 6 is a schematic view illustrating testing of a semiconductor chip at a wafer level using an interface device for wireless testing according to a fifth exemplary embodiment of the inventive concept. Referring to FIG. 6, a semiconductor device 50 includes a semiconductor chip 51 at a wafer level, and an interface device for wireless testing 53 according to the fifth exemplary embodiment of the inventive concept disposed on the semiconductor chip 51, which communicates signals with a wireless probe card 59 in a test process.

The interface device for wireless testing 53 according to the fifth exemplary embodiment includes at least two interface substrates 54a and 54b, in which interface antennas 57 may be disposed on the upper interface substrate 54a, and interface transmitting and receiving circuits 56 may be disposed on the lower interface substrate 54b. Interface pads (not shown) may be further disposed on a lower surface of the lower interface substrate 54b.

In the fifth exemplary embodiment, the interface antennas 57 are electrically connected to the interface transmitting and receiving circuits 56 via upper interface interconnections 58ia disposed on the upper interface substrate 54a and upper interface vias 58va passing through the upper interface substrate 54a, and the interface transmitting and receiving circuits 56 may be electrically connected to input/output pads 52 of the semiconductor chip via lower interface interconnections 58ib disposed on the lower interface substrate 54b and lower interface vias 59vb passing through the lower interface substrate 54b. Interface pads may be further disposed on an upper or lower surface of the lower interface substrate 54b. In this case, the interface transmitting and receiving circuits 56 are electrically connected to the interface pads, which may be electrically connected to the input/output pads 52 of the semiconductor chip. Since details of the present exemplary embodiment can be sufficiently inferred from the above figures and the corresponding descriptions, they will not be described.

In the fifth exemplary embodiment, although the interface antennas 57, the interface transmitting and receiving circuits 56, and the input/output pads 52 of the semiconductor chip are shown not to overlap with each other, they may be disposed to be aligned and overlap with one another. That is, the interface antennas 57, the interface transmitting and receiving circuits 56, and the input/output pads 52 of the semiconductor chip may be directly connected to one another through the upper and lower interface vias 58va and 58vb. Alternatively, only the interface antennas 57 and the interface transmitting and receiving circuits 56 may be disposed to be aligned and overlap with each other via the upper interface vias 58va. Alternatively, only the interface transmitting and receiving circuits 56 and the input/output pads 52 of the semiconductor chip may be disposed to be aligned and overlap with each other via the lower interface vias 58vb. Since details of exemplary embodiments in which the interface pads are formed can be sufficiently inferred from the above description, they will not be described in connection with the present embodiment.

In the fifth exemplary embodiment, the input/output pads 52 of the semiconductor chip are shown as being disposed in a central portion thereof, the interface transmitting and receiving circuits 56 are disposed at edges of the lower interface substrate 54b, and the interface antennas 57 are disposed in a central portion of the upper interface substrate 54a. Other relative positions of the various components are possible and equally applicable to the present inventive concept.

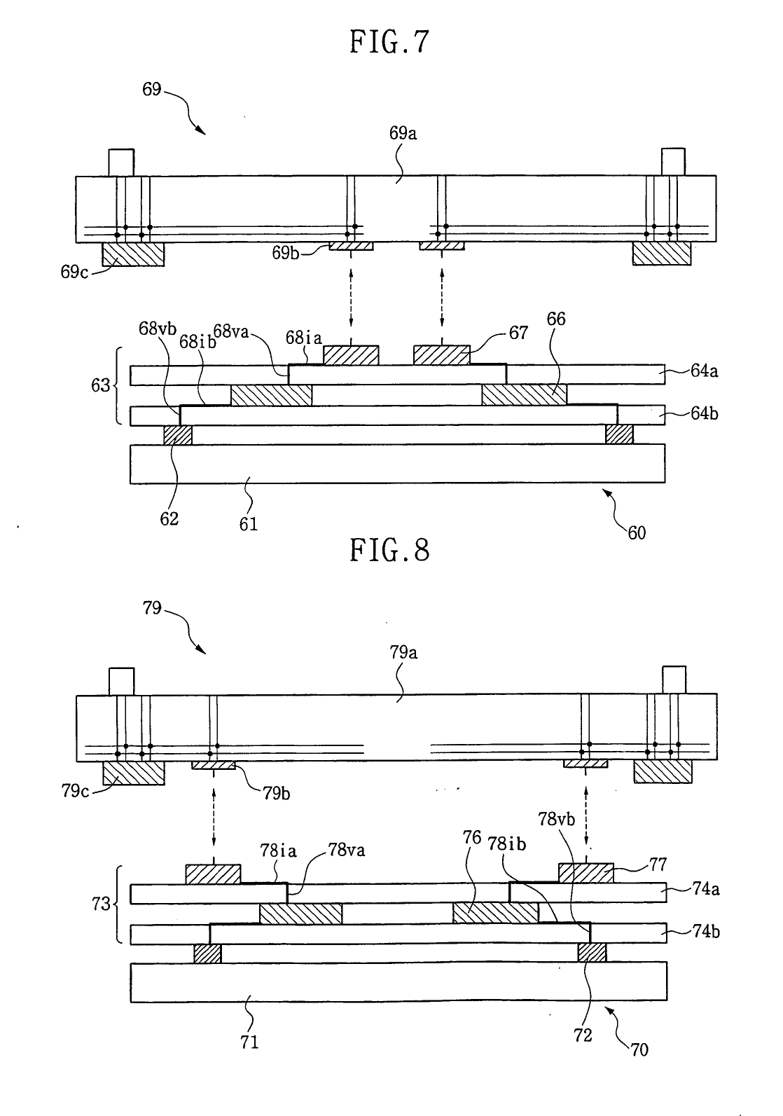

FIG. 7 is a schematic view illustrating testing of a semiconductor chip at a wafer level using an interface device for wireless testing according to a sixth exemplary embodiment of the inventive concept. Referring to FIG. 7, a semiconductor device 60 includes a semiconductor chip 61 at a wafer level, and an interface device for wireless testing 63 according to the sixth exemplary embodiment of the inventive concept disposed on the semiconductor chip 61, which communicates signals with a wireless probe card 69 in a test process.

The interface device for wireless testing 63 according to the sixth exemplary embodiment of the inventive concept can be properly applied when input/output pads 62 of the semiconductor chip 61 are disposed at edges of the semiconductor chip 61. The interface device for wireless testing 63 includes at least two interface substrates 64a and 64b, in which interface antennas 67 are arranged in a central portion on the upper interface substrate 64a, and interface transmitting and receiving circuits 66 are disposed on the lower interface substrate 64b between the positions of the input/output pads 62 of the semiconductor chip and the interface antennas 67.

FIG. 8 is a schematic view illustrating testing of a semiconductor chip at a wafer level using an interface device for wireless testing according to a seventh exemplary embodiment of the inventive concept. Referring to FIG. 8, the semiconductor device 70 includes a semiconductor chip 71 at a wafer level, and an interface device for wireless testing 73 according to the seventh exemplary embodiment of the inventive concept disposed on the semiconductor chip 71, which communicates signals with a wireless probe card 79 in a test process.

In the embodiment of FIG. 8, input/output pads 72 of the semiconductor chip are disposed at edges of the semiconductor chip 71. The interface device for wireless testing 73 according to the seventh exemplary embodiment of the inventive concept includes at least two interface substrates 74a and 74b, in which interface antennas 77 are disposed at outer edges of the upper interface substrate 74a, and interface transmitting and receiving circuits 76 are disposed in portions on the lower interface substrate 74b that are more centrally located than the antennas.

In the seventh exemplary embodiment, the input/output pads 72 of the semiconductor chip and the interface antennas 77 on the upper interface substrate 74a are all disposed on outer edges of the die of the semiconductor chip 71 at the wafer level.

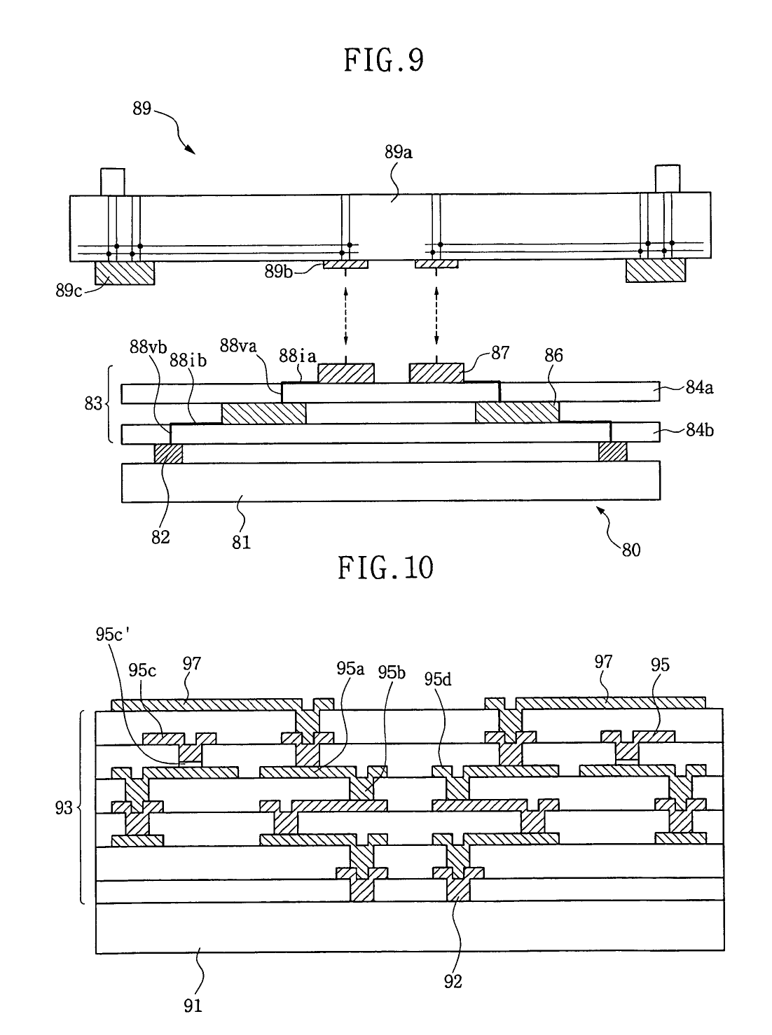

FIG. 9 is a schematic view illustrating testing of a semiconductor chip at a wafer level using an interface device for wireless testing according to an eighth exemplary embodiment of the inventive concept. Referring to FIG. 9, the semiconductor device 80 includes a semiconductor chip 81 at a wafer level, and an interface device for wireless testing 83 according to the eighth exemplary embodiment of the inventive concept disposed on the semiconductor chip 81, which communicates signals with a wireless probe card 89 in a test process.

Input/output pads 82 of the semiconductor chip are disposed at outer edge regions of the semiconductor chip 81. The interface device for wireless testing 83 according to the eighth exemplary embodiment of the inventive concept includes at least two interface substrates 84a and 84b, in which interface antennas 87 are disposed in a central portion on the upper interface substrate 84a, and interface transmitting and receiving circuits 84 are disposed on the lower interface substrate 84b between the input/output pads 82 of the semiconductor chip and the interface antennas 87.

In the eighth exemplary embodiment, the input/output pads 82 of the semiconductor chip are disposed at the outer edge regions defined by the semiconductor chip 81, and the interface antennas 87 on the upper interface substrate 84a are disposed in a central region thereof.

In the first to eighth exemplary embodiments of the inventive concept, the respective components may be electrically connected to each other via the conductive interface vias passing through the interface substrates.

In the exemplary embodiments of the inventive concept, the interface substrates may include two or more interface substrates, the interface transmitting and receiving circuits may be distributed over the two or more interfaces, and the interface pads may be disposed on each interface layer. The interface antennas may be disposed on the top of the interface device.

FIG. 10 is a view illustrating a semiconductor chip implemented using a wafer level redistribution scheme according to the inventive concept.

FIG. 10 is a conceptual cross-sectional view illustrating a semiconductor chip at a wafer level including an interface redistribution structure for wireless testing according to a ninth exemplary embodiment of the inventive concept. Referring to FIG. 10, a semiconductor device 90 includes a semiconductor chip 91 at a wafer level, and an interface redistribution structure 93 for wireless testing according to the ninth exemplary embodiment of the inventive concept disposed on the semiconductor chip 91.

The interface redistribution structure 93 according to the ninth exemplary embodiment of the inventive concept is formed on the semiconductor chip 91 using a wafer-level redistribution scheme. The interface redistribution structure 93 according to the ninth exemplary embodiment of the inventive concept includes a plurality of interconnections 95a, redistribution vias 95b, and redistribution capacitors 95c. The interface redistribution structure 93 may further include redistribution pads 95d. Interface antennas 97 may be formed on the top of the interface redistribution structure 93.

The interface redistribution structure 93 can constitute a circuit in itself and can be formed as a multi-layered configuration. The interface redistribution structure 93 may be fabricated in a semiconductor production line, and can be formed of insulating layers and conductive interconnections. Each insulating layer can be formed of a silicon oxide layer, a silicon nitride layer, a silicon oxynitride layer, or polyimide and each conductive interconnection can be formed of metal.

The redistribution capacitors 95c can each comprise a redistribution capacitor dielectric layer 95c′.

The interface antennas 97 may be disposed at any location, as described above.

The interface redistribution structure 93 may include thin film transistors, which are omitted from FIG. 10 for simplicity. In a case where the interface redistribution structure 93 includes the thin film transistors, a specific portion of the conductive lines or the insulating layers in the interface redistribution structure 93 can be formed of n- or p-type doped silicon.

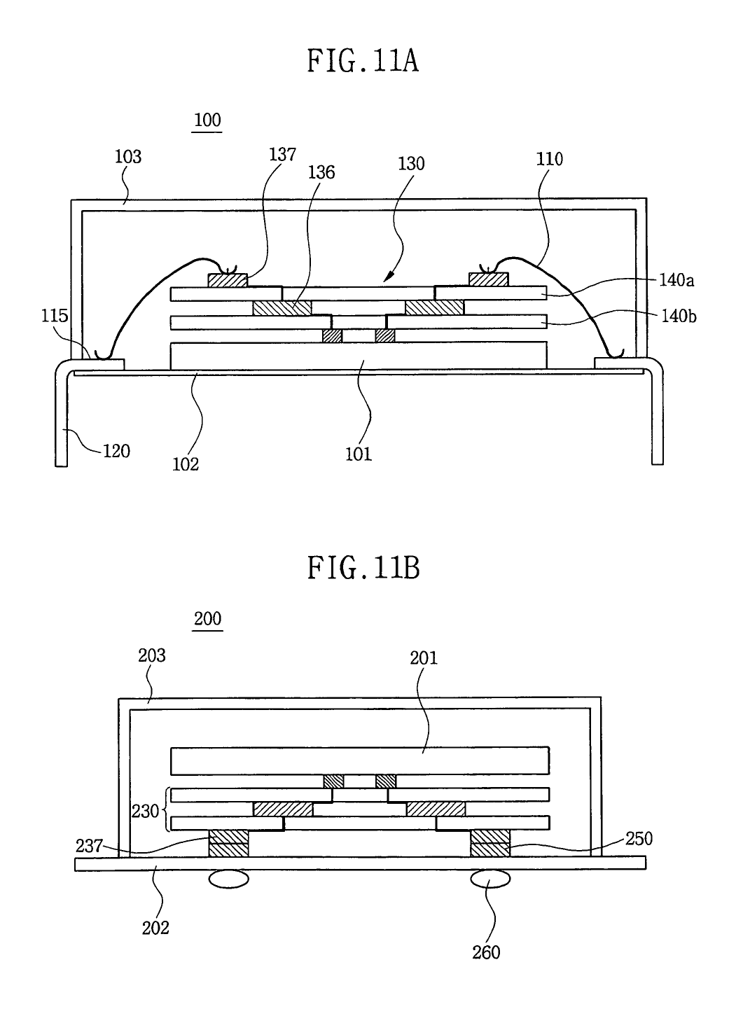

FIGS. 11A and 11B are schematic cross-sectional views illustrating semiconductor packages having an interface device for wireless testing according to exemplary embodiments of the inventive concept. Referring first to FIG. 11A, a semiconductor package 100 according to an exemplary embodiment of the inventive concept includes at least one interface device for wireless testing 130 according to the exemplary embodiments of the inventive concept, bonding wires 110 electrically connected to interface antennas 137, and input/output pins 120 electrically connected to the bonding wires 110. The bonding wires 110 may be electrically connected to the input/output pins 120 via lead frames 115.

The semiconductor package 100 can include a lower support package substrate 102 and an upper package cover 103 that externally covers a semiconductor chip 101, and can be filled with epoxy resin.

The interface device 130 includes interface transmitting and receiving circuits 136 and interface antennas 137 that are disposed on at least two interface substrates 140a and 140b. The interface antennas 137 can function as pads that are physically connected to the bonding wires 110. The bonding wires 110 can be electrically connected to the input/output pins 120 directly or via the lead frames 115.

In the exemplary embodiments of the inventive concept as described above, the interface antennas can be electrically connected to the bonding wires. That is, the interface antennas may also serve as the input/output pads of the semiconductor chip at a wafer level. Accordingly, the interface devices according to the exemplary embodiments of the inventive concept can serve to redistribute the positions of the input/output pads of the semiconductor chip. Accordingly, the interface devices can serve to compensate for standards for semiconductor chips, as needed.

FIG. 11B is a schematic longitudinal sectional view illustrating a semiconductor package assembled using a flip chip configuration, which is one package on a chip scale. Referring to FIG. 11B, a semiconductor package 200 according to another exemplary embodiment of the inventive concept includes one interface device for wireless testing 230 according to the exemplary embodiments of the inventive concept, a package substrate 202 having bumps 250 electrically connected to interface antennas 237, and a package cover 203. Solder balls 260 to be electrically connected to a circuit substrate may be disposed on a surface of the package substrate 202 opposing the bumps 250. The bumps 250 may be electrically connected to the solder balls 260. Alternatively, the interface antennas 237 may be directly connected to conductive interconnections (not shown) on the package substrate without the bumps 250.

In the present exemplary embodiment, one of the types of semiconductor packages that may be applied to a package on a chip scale has been illustrated and described. Other types of semiconductor packages are equally applicable to the principles of the embodiments of the present invention.

The interface device for wireless testing having the various structures according to the exemplary embodiments of the inventive concept can include two or more layers, which results in an increased component layout space. Furthermore, the respective components can be disposed with a sufficient spacing, which prevents interference or collision between signals. Since difficulty in increasing vertical integration can be overcome without the need for an increased horizontal area, a high-integration interface device can be achieved and more semiconductor chips can be obtained from a given wafer area.

With an interface device for wireless testing, and a semiconductor device and a semiconductor package including the same according to the exemplary embodiments of the inventive concept, increased integration of the semiconductor chip can be achieved. The interface device can comply with various semiconductor standards. Furthermore, the components can exhibit stable performance without interference or collision between them.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages. Accordingly, all such modifications are intended to be included within the scope of this invention as defined in the claims.

What is claimed is:

1. An interface device for wireless testing comprising:
an interface substrate;
coil shaped interface antennas on the interface substrate; and
interface transmitting and receiving circuits on the interface substrate electrically connected to the interface antennas via interface interconnections on the interface substrate, wherein the interface transmitting and receiving circuits are electrically connected to input/output pads of a semiconductor chip via interface vias passing through the interface substrate.

2. The interface device according to claim 1, wherein the interface substrate comprises an insulating hard substrate, the insulating hard substrate being one of a printed circuit board (PCB) substrate, a plastic substrate, a glass substrate, and a ceramic substrate.

3. The interface device according to claim 1, wherein the interface device is a redistribution structure formed on the wafer.

4. The interface device according to claim 1, wherein the interface substrate comprises at least two layers comprising an upper interface substrate and a lower interface substrate.

5. The interface device according to claim 4, wherein the interface vias comprise upper interface vias passing through the upper interface substrate, and lower interface vias passing through the lower interface substrate.

6. The interface device according to claim 5, wherein the interface antennas are disposed on the upper interface substrate and the interface transmitting and receiving circuits are disposed on the lower interface substrate.

7. The interface device according to claim 6, wherein the upper interface vias electrically connect the interface antennas to the interface transmitting and receiving circuits, and the lower interface vias electrically connect the interface transmitting and receiving circuits to the input/output pads of the semiconductor chip.

8. The interface device according to claim 1, further comprising interface pads disposed between the interface transmitting and receiving circuits and the input/output pads of the semiconductor chip, for electrically connecting the interface transmitting and receiving circuits to the input/output pads of the semiconductor chip.

9. The interface device according to claim 1, wherein the input/output pads of the semiconductor chip are disposed in a central region on an upper surface of the semiconductor chip, and wherein the interface antennas are disposed in a region corresponding to outer edges of the interface substrate.

10. A semiconductor device comprising:
a semiconductor chip at a wafer level;
input/output pads on the semiconductor chip; and
an interface device for wireless testing on the semiconductor chip,
wherein the interface device comprises:
an interface substrate;
interface antennas on the interface substrate; and
interface transmitting and receiving circuits on the interface substrate electrically connected to the interface antennas via interface interconnections on the interface substrate, wherein the interface transmitting and receiving circuits are electrically connected to the input/output pads of the semiconductor chip via interface vias, and the interface vias pass through the interface substrates.

11. The semiconductor device according to claim 10, wherein the interface substrate comprises an insulating hard substrate, the insulating hard substrate being one of a PCB substrate, a plastic substrate, a glass substrate, a polymer substrate, and a ceramic substrate, wherein each interface antenna comprises a polygonal or circular coil, and wherein each interface transmitting and receiving circuit comprises a transmitting circuit and a receiving circuit that in turn comprise resistors, capacitors and transistors.

12. The semiconductor device according to claim 10, wherein the interface substrate comprises at least two layers comprising an upper interface substrate and a lower interface substrate, and wherein the interface antennas are disposed on the upper interface substrate and the interface transmitting and receiving circuits are disposed on the lower interface substrate.

13. The semiconductor device according to claim 12, wherein the interface vias comprise:
upper interface vias passing through the upper interface substrates for electrically connecting the interface antennas to the interface transmitting and receiving circuits; and
lower interface vias passing through the lower interface substrates for electrically connecting the interface transmitting and receiving circuits to the input/output pads of the semiconductor chip.

14. The interface device according to claim 10, wherein the interface device is a redistribution structure formed on an upper part of the wafer.

15. A semiconductor package comprising:
a semiconductor chip;
input/output pads on the semiconductor chip; and
an interface device for wireless testing formed on the semiconductor chip,
wherein the interface device comprises:
an interface substrate;
interface antennas on the interface substrate; and
interface transmitting and receiving circuits on the interface substrate electrically connected to the interface antennas via interface interconnections on the interface substrate, wherein the interface antennas are electrically connected to the input/output pins via bonding wires.

16. The semiconductor package according to claim 15, wherein the interface substrate comprises at least two layers comprising an upper interface substrate and a lower interface substrate, and wherein the interface antennas are disposed on the upper interface substrate and the interface transmitting and receiving circuits are disposed on the lower interface substrate.

17. The semiconductor package according to claim 16, further comprising upper interface vias passing through the upper interface substrates for electrically connecting the interface antennas to the interface transmitting and receiving circuits.

18. A semiconductor package comprising:
a semiconductor chip;
input/output pads on the semiconductor chip; and
an interface device for wireless testing formed on the semiconductor chip,
wherein the interface device comprises:
an interface substrate;
interface antennas on the interface substrate; and
interface transmitting and receiving circuits on the interface substrate electrically connected to the interface antennas via interface interconnections on the interface substrate, wherein the interface antennas are electrically connected to external solder balls via bumps.

19. The semiconductor package according to claim 18, wherein the interface substrate comprises at least two layers comprising an upper interface substrate and a lower interface substrate, and wherein the interface antennas are disposed on the upper interface substrate and the interface transmitting and receiving circuits are disposed on the lower interface substrate.

20. The semiconductor package according to claim 19, further comprising upper interface vias passing through the upper interface substrates for electrically connecting the interface antennas to the interface transmitting and receiving circuits.
